(19) United States
(12) Patent Application Publication
(10) Pub. No.: US 2005/0067694 A1
(43) Pub. Date: Mar. 31, 2005

(54) Spacerless die stacking

(76) Inventors: Florence R. Pon, Folsom, CA (US); Steven R. Eskildsen, Folsom, CA (US); Robert Jai Kim, Shingle Springs, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/676,961

(22) Filed: Sep. 30, 2003

(51) Int. Cl. H01L 21/50

(52) U.S. Cl. 257/723; 438/107

(57) ABSTRACT

An embodiment of the present invention is a technique to stack dies in a die assembly. A plurality of dies are stacked on top of one another in a staggering configuration such that an upper die top surface in a pair of adjacent dies faces downward or upward and is displaced by a first distance with respect to a lower die in the pair. The adjacent dies are attached by an adhesive layer between the adjacent dies.

### BACKGROUND

1. Field of the Invention

Embodiments of the invention relate to the field of semiconductor, and more specifically, to device packaging.

2. Description of Related Art

Spacers are elements that are used to elevate same or similar sized die that are stacked one above another so that the bond pads on the die below are not covered up. Spacers can be made of various materials including silicon, polymer films, or polymer pastes with filter particles. This adds the elevation (z) height for every spacer that is used resulting in high thickness of the die assembly.

Existing techniques have a number of disadvantages. One method is to thin the wafer. However, there is a limit on how thin the wafer can be. In addition, thinning the wafer may have problems in grinding, polishing, and handling.

### BRIEF DESCRIPTION OF THE DRAWINGS

The invention may best be understood by referring to the following description and accompanying drawings that are used to illustrate embodiments of the invention. In the drawings:

FIG. 1A is a diagram illustrating a package assembly in which one embodiment of the invention can be practiced.

FIG. 1B is a diagram illustrating a pair of adjacent dies in the stack according to one embodiment of the invention.

FIG. 2A is a diagram illustrating a cross-sectional view of a stair-case configuration according to one embodiment of the invention.

FIG. 2B is a diagram illustrating a top view of a stair-case configuration according to one embodiment of the invention.

FIG. 3 is a diagram illustrating a top view of a stair-case configuration in both dimensions according to one embodiment of the invention.

FIG. 4A is a diagram illustrating a cross-sectional view of an alternate staggering configuration according to one embodiment of the invention.

FIG. 4B is a diagram illustrating a top view of an alternate staggering configuration according to one embodiment of the invention.

FIG. 5 is a diagram illustrating a top view of an alternate staggering configuration in both dimensions according to one embodiment of the invention.

FIG. 6 is a flowchart illustrating a process to stack the dies according to one embodiment of the invention.

### DESCRIPTION

An embodiment of the present invention is a technique to stack dies in a die assembly. A plurality of dies are stacked on top of one another in a staggering configuration such that an upper die in a pair of adjacent dies face downward or upward and is displaced by a first distance with respect to a lower die in the pair. The adjacent dies are attached by an adhesive layer between the adjacent dies.

In another embodiment, an upper die having upper first, second, third, and fourth edges is stacked on top of a lower die having lower first, second, third, and fourth edges such that the upper first edge is displaced from the lower first edge by a first distance. The upper first and third edges are opposite to each other. The lower first and third edges are opposite to each other. The upper die is attached to the lower die by a first adhesive layer deposited between the upper and lower dies

In the following description, numerous specific details are set forth. However, it is understood that embodiments of the invention may be practiced without these specific details. In other instances, well-known circuits, structures, and techniques have not been shown in order not to obscure the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a procedure, a method of manufacturing or fabrication, etc.

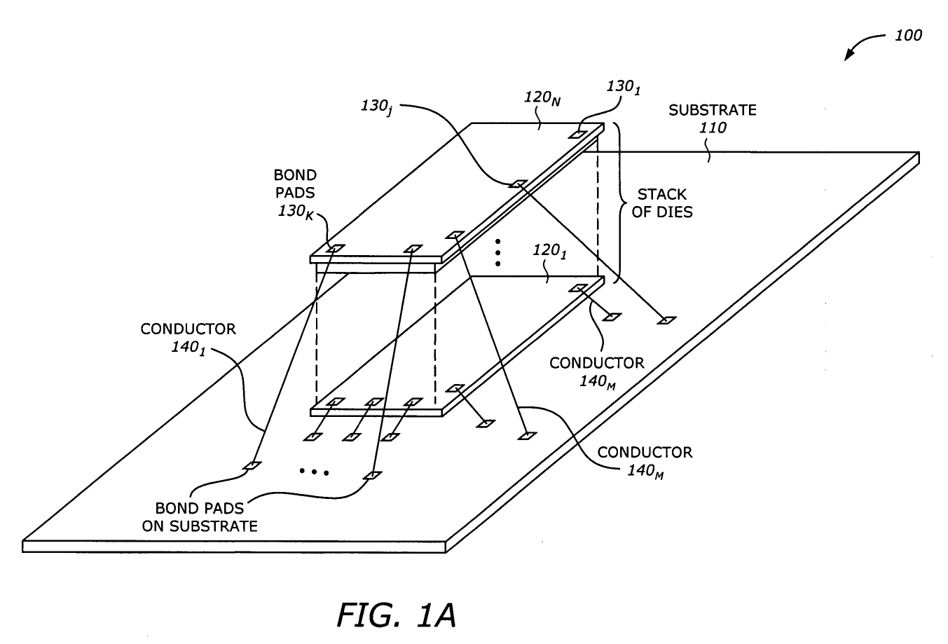

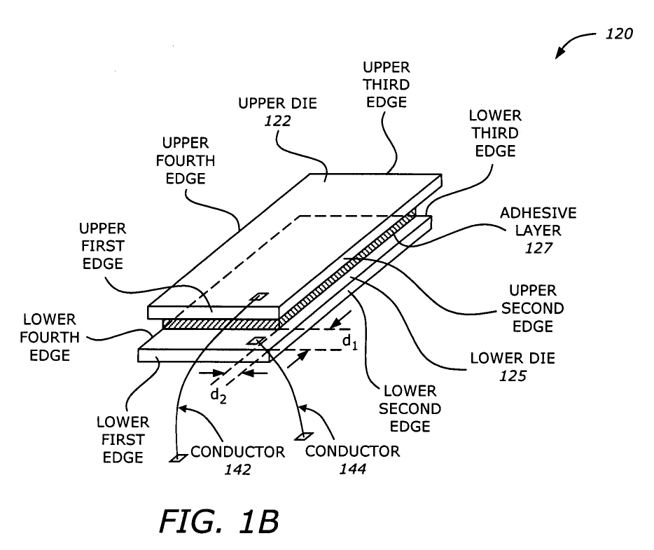

FIG. 1A is a diagram illustrating a package assembly 100 in which one embodiment of the invention can be practiced. The package assembly includes a substrate 110, a plurality of dies 120₁ to 120_{N}, a plurality of bond pads 130, to 130_{K}, and a plurality of conductors 140, to 140_{M}.

The substrate 110 is any suitable substrate made of material such as silicon. The substrate 110 may also be a printed circuit board (PCB). The substrate 110 has a number of bond pads to provide interconnections to the dies. The plurality of dies 120₁ to 120_{N} form a stack and include dies stacked on top of one another. Each die is an integrated circuit (IC) or a chip. The number of dies in the stack may be any suitable number, odd or even, depending on the desired height. For example, the number of dies may be 4, 5, 6, 9 or 10.

Each of the dies has a number of bond pads 130ⱼ's (j=1, . . . , K) to provide contact for interconnections. The number of bond pads on each die may vary. When the bond pads are not suitably placed, a redistribution layer (not shown) may be formed to redistribute the interconnection pattern. The conductors 140ₖ's (i=1, . . . , M) connect the bond pads from the dies to the bond pads on the substrate. The conductors 140ₖ's may be wires or conducting material or paths that form electrical connections between the bond pads.

The dies in the stack are arranged in a staggering pattern. The staggering configuration may be stair-case in one dimension or two dimensions, or alternate. The staggering configuration allows the adjacent dies to be placed off-center, i.e., adjacent dies are displaced with respect to each other by a distance. The distance is selected so that the conductors connecting the bond pads on the dies to the bond pads on the substrate 110 are separated by a conductor distance to avoid touching or crossing each other.

By offsetting the dies with respect to one another in the stack, no spacers are needed. The dies in essence act like the spacers themselves. The advantages of offsetting the dies in the stack includes more dies for a given height, reduced assembly time, and increased reliability and yield dues to less interfacing problems.

FIG. 1B is a diagram illustrating a pair 120ₖ of adjacent dies in the stack according to one embodiment of the invention. The pair 120ₖ includes an upper die 122 and a lower die 125 and an adhesive layer 127. The stack 120 includes a number of layers having a number of pairs 120ₖ stacked on top of one another. The number of layers may be odd or even. The upper and lower dies 122 and 125 may have same or substantially similar sizes and/or geometries.

The upper die 122 has four edges: upper first, second, third, and fourth edges. The upper first and third edges are opposite to each other and the upper second and fourth edges are opposite to each other. Typically, the upper die 122 is square or rectangle. Therefore, the upper first and third edges are parallel to each other and the upper second and fourth edges are parallel to each other.

Similarly, the lower die 125 has four edges: lower first, second, third, and fourth edges. The lower first and third edges are opposite to each other and the lower second and fourth edges are opposite to each other. Typically, the lower die 122 is square or rectangle. Therefore, the lower first and third edges are parallel to each other and the lower second and fourth edges are parallel to each other.

The upper die 122 is stacked on top of the lower die 125 such that the upper first edge is displaced from the lower first edge by a first distance d₁. The upper die 122 may also be displaced by any angle with respect to the lower die 125. The stacking may also extended to the other dimension such that the upper second edge is displaced from the lower second edge by a second distance d₂. The adhesive layer deposited between the upper and lower dies 122 and 125 to attach these two dies together. In one embodiment, the adhesive layer is made of an adhesive material such as epoxy and can be filled with non-conductive or conductive particles.

The upper die 122 and the lower die 125 may be stacked as shown in FIG. 11B, i.e., the bottom surface of the upper die 122 is attached to the top surface of the lower die 125. In another embodiment, the top of the upper die 122 and the top of the lower die 125 may face to each other. In other words, the upper die 122 is turned upside down such that its upper surface is attached to the upper surface of the lower die 125. The two dies can be stacked in any configuration, as long as there is an unobstructed area for the bond pads. This unobstructed area may face upward or downward depending on whether the corresponding die faces upward or downward, respectively.

For interconnection, the conductors are connected or attached to the bond pads of the dies. For example, upper conductor 142 is attached to the upper bond pad of the upper die 122 and lower conductor 144 is attached to the lower bond pad of the lower die 125. Since the dies are offset to each other by a distance, the upper conductor 142 and the lower conductor 144 are separated by a conductor distance. When the bond pads face downward, the resulting conductor interconnections may provide space efficiency and/or design flexibility for the layout on the substrate surface.

The stack of dies 120 includes any number of layers including pairs like the pair 120ₖ stacked on top of one another. Depending on how these pairs are stacked on one another, there are a number of staggering configurations of the entire stack. Examples of these configurations include a stair-case configuration in one dimension, a stair-case configuration in both dimensions, an alternate staggering configuration in one dimension, and an alternate staggering configuration in both dimensions.

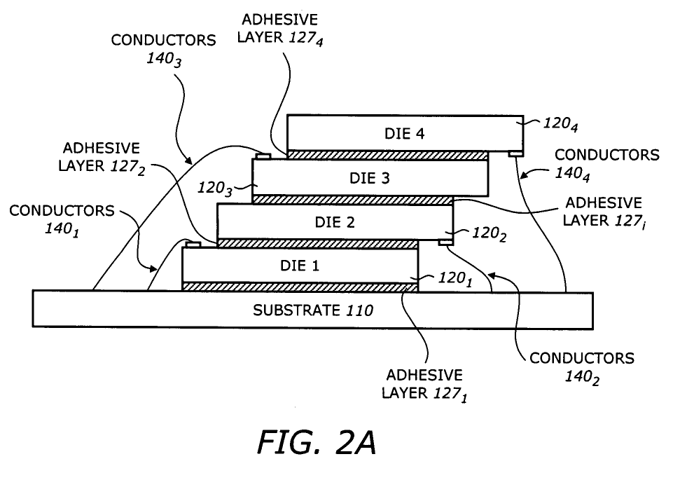

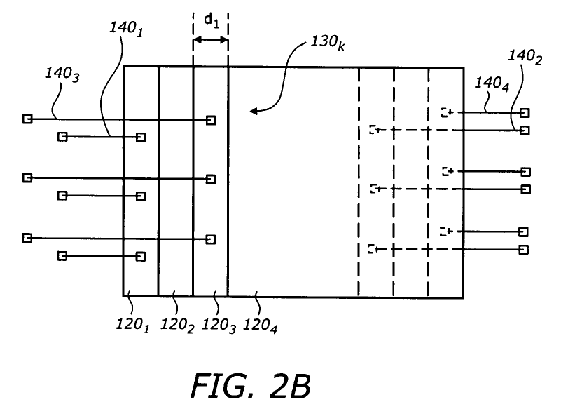

FIG. 2A is a diagram illustrating a cross-sectional view of a stair-case configuration according to one embodiment of the invention. For illustrative purposes, four dies are shown.

The four dies 120₁ to 120₄ are arranged in a stair-case configuration. In this configuration, the dies are offset by a distance in a stair-case pattern. Between adjacent dies, there is an adhesive layer 127ᵢ's (i=1, . . . , 4) to attach the adjacent dies together. The thickness of the adhesive layer may be 0.001″. Since the thickness of the adhesive layer 127ᵢ's is much less than that of a conventional spacer, more dies can be stacked together for the same height. The bottom die 120₁ is attached to the substrate by the same adhesive layer 127₁.

The conductors 140₁ to 140₄ are representative of conductors connecting the die bond pads to the substrate bond pads. Since the dies are offset by a distance, the conductors 140₁ to 140₄ are also offset by a conductor distance sufficiently large to separate the conductors. The conductors 140₄ and 140₂ are shown beneath the corresponding die 120₄ and 120₂ because these two dies face downward to the respective lower dies. The dies are stacked in pairs by having the two dies in each pair face to each other, i.e., their upper surfaces are attached by the adhesive layer. As shown in FIG. 2A, dies 2 and 4 120₂ and 120₄ are turned upside down so that the exposed bond path faces downward.

FIG. 2B is a diagram illustrating a top view of a stair-case configuration according to one embodiment of the invention. For illustrative purposes, four dies are shown.

The dies are offset by a distance d₁. The distance d₁ may be the same or different for each pair of adjacent dies. In addition, the distance d₁ may be constant or variable depending on the relative orientation of the two adjacent dies. The conductors 140ⱼ's connect the bond pads of the dies on the stair-case side of the stack.

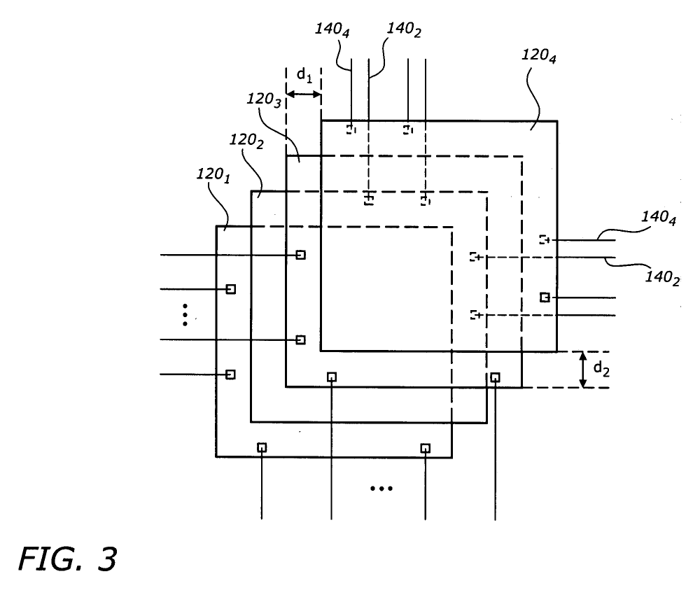

FIG. 3 is a diagram illustrating a top view of a stair-case configuration in both dimensions according to one embodiment of the invention. For illustrative purposes, four dies are shown.

In this configuration, the dies are offset in both directions or dimensions by distances d₁ and d₂. The conductors connect the bond pads on both stair-case sides of each die to the bond pads of the substrate. As in FIG. 2B, the dies 120₂ and 120₄ face toward their respective lower dies, i.e., die 120₁ and 120₃, respectively. The conductors 140₂ and 140₄ are connected to the bond pads on the dies 120₂ and 120₄ facing downward.

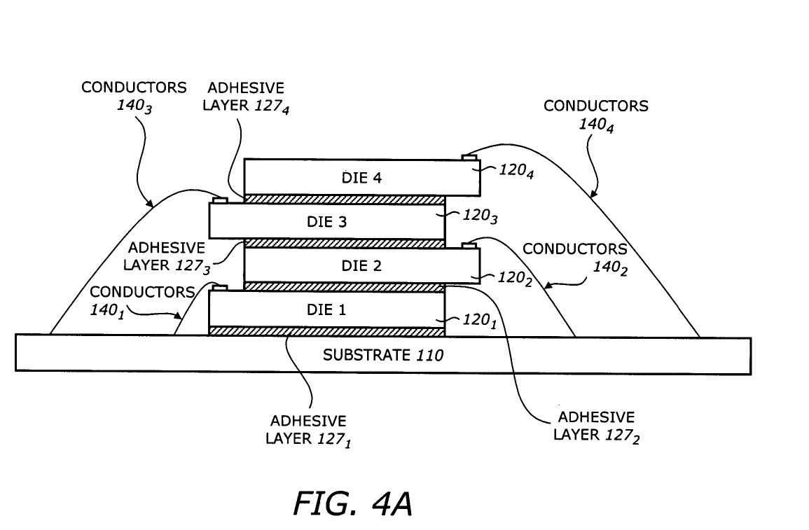

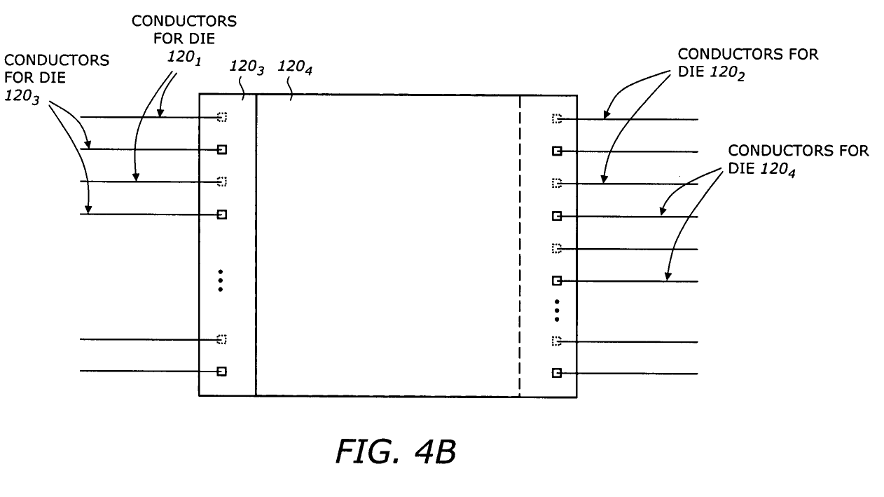

FIG. 4A is a diagram illustrating a cross-sectional view of an alternate staggering configuration according to one embodiment of the invention. For illustrative purposes, four dies are shown.

In this configuration, the dies 120₁ to 120₄ are arranged in a zigzag or alternate pattern. Dies form in pairs of adjacent dies. The dies may face together in the same direction or in opposite directions. In each pair, the upper die is offset from the lower die by a distance. The pairs are then stacked onto one another in alignment, resulting in an alternate staggering pattern. For example, dies 120₁ and 120₃ are aligned and dies 120₂ and 102₄ are aligned.

In another embodiment, in each pair, the dies may face toward each other, i.e., the upper die is turned upside down as discussed above.

The conductors 140ⱼ's are connecting the bond pads in both sides of the dies. On one side, the conductors 140ⱼ's connect the bond pads of the lower dies in the pairs to one side of the substrate. On the other side, the conductors 140ⱼ's connect the bond pads of the upper dies in the pairs to the other side of the substrate.

FIG. 4B is a diagram illustrating a top view of an alternate staggering configuration according to one embodiment of the invention. For illustrative purposes, four dies are shown.

In this top view, only the upper pair is visible showing the dies 120₃ and 120₄. The lower pair including the dies 120₁ and 120₂ are hidden as viewed from the top. The conductors are shown to connect the bond pads of the dies to the bond pads of the substrate on both opposite sides of the stack of dies.

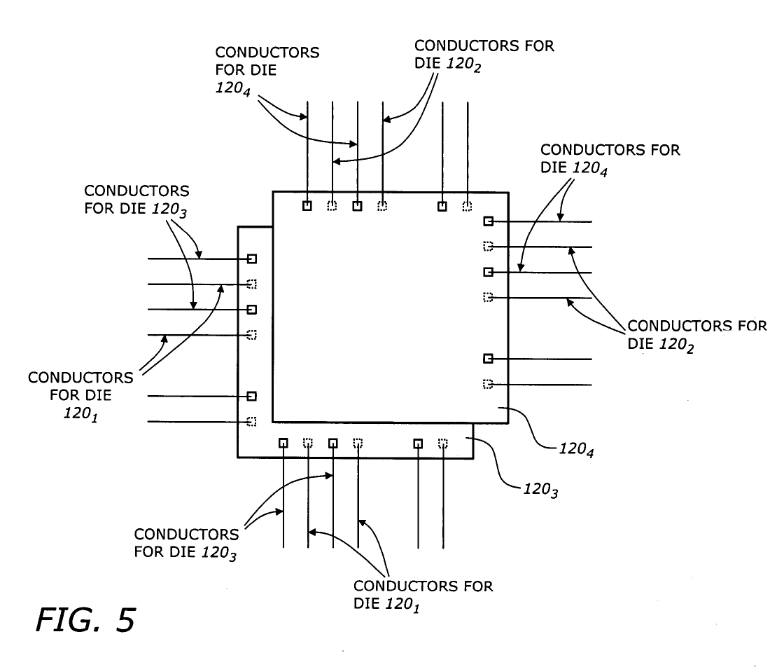

FIG. 5 is a diagram illustrating a top view of an alternate staggering configuration in both dimensions according to one embodiment of the invention. For illustrative purposes, four dies are shown.

In this configuration, the dies are arranged in the alternate staggering pattern in both directions or dimensions. As seen from the top, only the upper pair is visible showing the dies 120₃ and 120₄. The lower pair including the dies 120₁ and 120₂ are hidden as viewed from the top. The conductors are shown to connect the bond pads of the dies to the bond pads of the substrate on all four sides of the stack of dies.

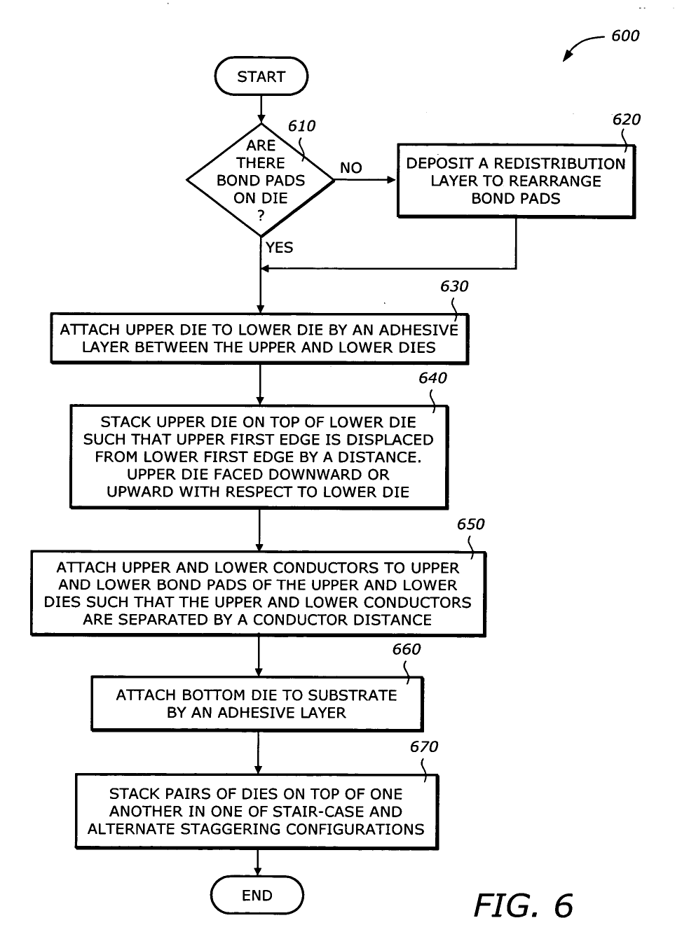

FIG. 6 is a flowchart illustrating a process 600 to stack the dies according to one embodiment of the invention.

Upon START, the process 600 determines if there are bond pads on the die at the exposed edges for interconnections (Block 610). If not, the process 600 deposits redistribution layer to re-arrange the bond pads to suitable locations (Block 620) and then goes to Block 630. Otherwise, the process 600 deposits an adhesive layer on the lower die to attach the lower die to the upper die (Block 630). The adhesive layer is deposited to cover sufficient surface areas between the two dies. Next, the process 600 stacks an upper die on top of a lower die such that the upper first edge is displaced from the lower first edge by a distance (Block 640). The upper and lower dies may have the geometry as shown in FIG. 1B. The upper die may face upward or downward with respect to the lower die.

Then, the process 600 attaches the upper and lower conductors to the upper and lower bond pads of the upper and lower dies, respectively, such that the conductors are separated by a conductor distance (Block 650).

Next, the process 600 attaches the bottom die in the stack to the substrate by an adhesive layer (Block 660). Then, the process 600 stacks dies on top of one another in one of a stair-case and alternate staggering configurations (Block 660) and is then terminated. The staggering or displacement of the dies may be parallel to a die edge or approximately diagonal to a die edge.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

1. A method comprising:
stacking an upper die having an upper top surface and upper first, second, third, and fourth edges on top of a lower die having a lower top surface and lower first, second, third, and fourth edges such that the upper first edge is displaced from the lower first edge by a first distance, the upper first and third edges being opposite to each other, the lower first and third edges being opposite to each other, the upper top surface facing toward the lower top surface; and
attaching the upper die to the lower die with an adhesive layer between the upper and lower dies.

2. The method of claim 1 further comprising:
attaching upper and lower conductors to upper and lower bond pads of the upper and lower dies at the upper and lower first edges, respectively, such that the upper and lower conductors are separated by a conductor distance.

3. The method of claim 1 further comprising:
attaching upper and lower conductors to upper and lower bond pads of the first and second dies at the upper third and the lower first edges, respectively.

4. The method of claim 1 wherein stacking the upper die comprises:
stacking the upper die on top of the second die such that the upper second edge is displaced from the lower second edge by a second distance.

5. The method of claim 4 further comprising:
attaching upper and lower conductors to upper and lower bond pads of the upper and lower dies at the upper and lower second edges, respectively, such that the upper and lower conductors are separated by a conductor distance.

6. The method of claim 1 further comprising:
attaching the lower die to a substrate by a second adhesive layer deposited between the lower die and the substrate.

7. The method of claim 1 further comprising:
depositing an upper redistribution layer to place bond pads on the upper die.

8. The method of claim 7 further comprising:
depositing a lower redistribution layer to place bond pads on the lower die.

9. The method of claim 1 wherein stacking the upper die comprises:
stacking the upper die on top of the lower die, the upper and lower die having same or substantially similar sizes.

10. The method of claim 1 wherein attaching comprises:
attaching the upper die to the lower die by the first adhesive layer made of a non-conductive or conductive material.

11. A method comprising:
stacking a plurality of dies on top of one another in a staggering configuration such that an upper die top surface in a pair of adjacent dies faces downward or upward and is displaced by a first distance with respect to a lower die in the pair; and
attaching the adjacent dies by an adhesive layer between the adjacent dies.

12. The method of claim 11 further comprising:
attaching conductors to bond pads of the adjacent dies such that the conductors are separated by a conductor distance.

13. The method of claim 11 wherein stacking comprises:
stacking the plurality of dies in a first stair-case configuration in a first dimension.

14. The method of claim 13 wherein stacking further comprises:
stacking the plurality of dies in a second stair-case configuration in a second dimension.

15. The method of claim 11 wherein stacking comprises:
stacking the plurality of dies in a first alternate staggering configuration in a first dimension.

16. The method of claim 15 wherein stacking further comprises:
stacking the plurality of dies in a second staggering configuration in a second dimension.

17. The method of claim 11 further comprising:
depositing a redistribution layer to place bond pads on at least one of the plurality of the dies.

18. The method of claim 11 wherein stacking comprises:
stacking the plurality of dies having same or substantially similar sizes.

19. The method of claim 11 wherein stacking comprises:
stacking the plurality of dies on top of a substrate; and
attaching a bottom die of the plurality of dies to the substrate by an adhesive.

20. The method of claim 11 wherein attaching comprises:
attaching the adjacent dies by the adhesive layer made of a non-conductive or conductive material.

21. A die assembly comprising:
a plurality of dies stacked on top of one another in a staggering configuration such that an upper die top surface in a pair of adjacent dies faces downward or upward and is displaced by a first distance with respect to a lower die in the pair; and
an adhesive layer between the adjacent dies to attach the adjacent dies.

22. The die assembly of claim 21 further comprising:
conductors attached to bond pads of the adjacent dies such that the conductors are separated by a conductor distance.

23. The die assembly of claim 21 wherein the plurality of dies are stacked in a first stair-case configuration in a first dimension.

24. The die assembly of claim 23 wherein the plurality of dies are stacked in a second stair-case configuration in a second dimension.

25. The die assembly of claim 21 wherein the plurality of dies are stacked in a first alternate staggering configuration in a first dimension.

26. The die assembly of claim 25 wherein the plurality of dies are stacked in a second staggering configuration in a second dimension.

27. The die assembly of claim 21 further comprising:
a redistribution layer to place bond pads on at least one of the plurality of the dies.

28. The die assembly of claim 21 wherein the plurality of dies having same or substantially similar sizes.

29. The die assembly of claim 21 further comprising:
a substrate attached to a bottom die of the plurality of dies by an adhesive.

30. The die assembly of claim 21 wherein the adhesive layer is made of a non-conductive or conductive material.
